(19) United States
(12) Patent Application Publication
(10) Pub. No.: US 2003/0095666 A1
(43) Pub. Date: May 22, 2003

(54) Machine for controlling and amplifying a low-level audio signal using a high efficiency class D switching amplifier

(76) Inventor: Robert D. Ramage, Groveland, MA (US)

Correspondence Address: MAINE & ASMUS, 100 MAIN STREET, P O BOX 3445, NASHUA, NH, 03061-3445, US

(21) Appl. No.: 10/158,434

(22) Filed: May 29, 2002

Related U.S. Application Data
(60) Provisional application No. 60/333,232, filed on Nov. 16, 2001.

(51) Int. Cl. H04H 5/00; H03F 21/00

(52) U.S. Cl. 381/2; 381/120

(57) ABSTRACT

An audio amplifying circuit and system for amplifying and broadcasting audio signals using high efficiency Class D switching amplifiers, consisting of a battery charger and batteries suitably sized to supply power to the system for operation at full output power for a predetermined time. The system may have a power conditioning section for converting input power directly into the necessary DC voltage used by the class D amplifiers. The system can deliver over 100 watts RMS in a small form factor to a suitable arranged and impedance matched acoustical transducers configured as either a single point acoustic source or in a distributed pattern. The system may provide audio coverage of either indoor or outdoor areas by adjusting the number and type of acoustic transducers, and be activated or controlled either remotely or locally to provide public notification and emergency warning messages.

This application relates and claims priority to pending U.S. application serial No. 60/333,232, filed Nov. 16, 2001.

### FIELD OF THE INVENTION

This invention relates generally to the field of a high power audio amplifier platform used for public broadcasting and emergency notification, and more particularly to a machine for controlling and amplifying a low level audio signal using a high efficiency class D switching amplifier.

### BACKGROUND OF THE INVENTION

There are four basic classes of amplifiers in common use for amplifying audio signals: class A, class B, class AB and class D. The extremely poor efficiency of class A amplifiers usually limits their use to applications of less than 15 watts for very low distortion applications. The class A audio amplifier has a large standby current flowing in its output power stage even in the absent of an input signal. This large current results in amplifier efficiency of less than 30% and therefore requires large heat sinks and fans in power applications. This large standby current, when no input signal is applied, makes the class A type of amplifier unsuitable for battery power applications. The class B amplifier requires no biasing current for their power output stage and therefore does not dissipate power in its output stage in standby mode. Thus, the class B amplifier can have output efficiencies approaching 80% depending on the input waveform and amplitude, but often suffers from high crossover distortion as a results of the lack of bias current and therefore are not commonly used for audio applications.

The class AB amplifier is by far the most commonly used configuration for audio amplifiers. The class AB amplifier with temperature compensated biasing of its output stage can have low standby power dissipation in its output stage, low crossover distortion, and efficiencies approaching 80%, depending on the input waveform and amplitude.

A class D or switching mode audio amplifier is a recent development brought about from advances in the switching power supply field. The class D audio amplifier can have output efficiencies of greater than 80% independent of the input waveform or amplitude. At present, there are several commercially available products on the market base on this newer class D technology with acceptable output distortion and the benefit of very high efficiency.

Examples of some commonly used circuit techniques for class D amplifiers are illustrated by referring to U.S. Pat. No. 4,249,136 issued Feb. 3, 1981, U.S. Pat. No. 6,078,214 issued Jun. 20, 2000 and U.S. Pat. No. 6,300,825 issued Oct. 9, 2001. However, since the target market is usually home entertainment where low average power voice and music waveforms are amplified, they are typically designed for peak output power of 100 watts or less and are directly coupled to the output speaker thereby obtaining a wide frequency response and simplicity.

The are a few companies that are presently marketing audio amplifiers of between 200 watts to 1200 watts of audio output power, but these commercially available products are not designed for continuous sustained output at their maximum power level, are not designed for battery power applications and are directly coupled to the speakers without using a transformer.

In the prior art, a high power audio platform used either a class B or class AB audio amplifier, with the class AB being the preferred choice due to lower output distortion. The class AB audio amplifier for the high power audio platform was designed to output usually from 100 to 400 watts of RMS power for durations of less than 10 minutes, thereby keeping its overall size small due to the reduced heat sink requirements. The high power audio platform was further designed to accommodate multiple audio amplifiers allowing for total output power normally in the range of from 100 watts to 3200 watts. Normally fans where not used due to reliability issues and since the amplifiers were housed in a NEMA type enclosure they had little long-term effectiveness.

In order to allow this type of audio amplifier to operate for longer durations when outputting continuous tones at maximum output power for extended time periods, often a saturated square wave input drive waveform was used. Examples of this type of drive technique can be found in U.S. Pat. No. 4,363,028 issued Dec. 7, 1982, U.S. Pat. No. 4,189,718 issued Feb. 19, 1980 and U.S. Pat. No. 4,180,809 issued Dec. 25, 1979. While this drive technique results in amplifier efficiency of greater than 80% and thus prevents the output stage from overheating, the acoustical transducer(s) suffer from increased mechanical stresses, poor transducer efficiency, increased heating and premature failures.

These high power audio platforms were often equipped with local tone generators, stored messages, means for live public announcements, diagnostics to determine operation readiness and proper operation when activated and a means to activate this unit either locally or remotely.

Thus, efficiency when using tones that are sinusoid, which increases the acoustic transducers efficiency and prolongs it life, are very important in the development of a practical high power audio amplifier platform that handles power levels greater than 100 watts RMS of continuous output power. As already noted the audio amplifier classes A, B and AB all suffer from poor amplifier power efficiency with the power efficiency also highly dependent upon the amplitude and shape of the input audio drive signal. The poor amplifier efficiency of class A, B and AB audio amplifiers results in their requiring large heat sinks and often fans in order dissipate the excessive heat produced during operation. Both the class A and AB have standby currents flowing in their power output stages that result in power usage and thus heat production even when the amplifier is not amplifying a input signal. In addition, care must be taken to prevent turn on and turn off transients at high power levels to prevent damage to the acoustic transducers.

Since class A, B and AB amplifiers have lower efficiency than a class D amplifier, and the class A and AB amplifiers draw current even in standby mode, larger power supplies or batteries are required in order to supply the extra energy that is dissipated as heat in the output stage. The requirement of large heat sinks and fans results in a much large unit than an equivalent output power class D amplifier. So, there are very clear advantages to using a class D audio amplifier for sustained power output of 100 watts RMS or greater.

Many attempts have been made to develop a high power, high efficiency switch mode or class D amplifier. Most commercial products presently on the market are limited to less than 100 watts of peak power and only capable of sustaining a continual output at that power level for short peak durations. A few companies are marketing amplifiers capable of outputting between 200 watts to 1200 watts of audio power but not for extended periods. Further, they usually use a direct drive technique for the speaker connections; matching the supply voltages to the speaker impedance requirements for the desired power output. This presents a problem with matching the impedances of the transducers with the output drive stage since high voltages are required to drive transducers at very high power levels. These high voltages are not easily obtained when using batteries. In fact, a single supply voltage that can be easily obtained from stacking two 12 volts DC batteries is desirable for this application.

### SUMMARY OF THE INVENTION

The applicant has discovered that by application of a variety of different design concepts and principles a class D amplifier platform is feasible that can drive output audio transducers with over 2000 watts of RMS power per amplifier using a single low voltage power source. This amplifier platform can use sine wave input drive for tone outputs thereby minimize transducer stress and maintain efficiency of over 80%.

It is therefore an object of the invention is the use of a high efficiency, high power class D amplifier that can replace five or more class A, B or AB amplifiers, requiring the same or less space. Another object of the invention is maintaining the efficiency of a class D amplifier at greater than 80% independent of the input waveform shape or amplitude. A further object of the invention is allowing the use of sine wave drive versus saturated square wave drive when producing continuous output tones resulting in less stress, lower heating, longer life and higher efficiency of output acoustical transducers.

Yet, another object of the invention is to use a class D amplifier that has very low or no output turn on or turn off popping, which is an erroneous output signal applied to the acoustic transducers during turn on or turn off. Still yet another object of the invention is a class D amplifier that has extremely low quiescent or standby current flowing when an audio input signal is not present. Another object of the invention is a class D amplifier that has little or no warm up or stabilizing period required after the amplifier power is first applied.

Another object of the invention is a class D amplifier that requires a smaller DC power source than would be necessary using a class A, B, AB amplifier, due to its much higher overall efficiency. A further object of the invention is a class D amplifier that requires a single low voltage supply for power that can easily be obtained by connecting standard batteries together.

Yet, another object of the invention is that the audio amplifier platform inputs can be electrically isolated from the outputs and impedance matched to the output acoustical transducers by using an output transformer on each amplifier.

Other objects and advantages of the present invention will become apparent from the following descriptions, taken in connection with the accompanying drawings, wherein, by way of illustration and example, an embodiment of the present invention is disclosed.

To these ends, there is disclosed a circuit and system for controlling, amplifying and broadcasting an audio signal using high efficiency Class D switching amplifiers; preferably utilizing a battery charger and batteries suitably sized to supply power to the circuit for operation at full output power for a predetermined time, but the system may be configured with a power conditioning section for converting AC or DC input power directly into the necessary DC voltage bus used by the class D amplifiers.

The system includes one or more high efficiency class D amplifiers capable of sustained output power of 100 watts RMS per amplifier or greater and design to accept multiple class D amplifiers. The class D amplifiers have an overhaul efficiency of greater than 80% independent of input waveform or input amplitude. The amplifiers can use either an isolated or non-isolated output transformer to allow for impedance matching to the output acoustical transducers.

The amplifiers use a single DC low voltage supply for power. The system allows tones, voice inputs, and other audio inputs and messages to be accessed either locally or remotely and broadcast by the system. A controller or computer in the system may include diagnostic capability to determine the readiness status of the system to broadcast audio messages and tones as controlled either from the local site or from a remote site.

The drawings constitute a part of this specification and include exemplary embodiments to the invention, which may be embodied in various forms. It is to be understood that in some instances various aspects of the invention may be shown exaggerated or enlarged to facilitate an understanding of the invention.

### BRIEF DESCRIPTION OF THE DRAWINGS

FIG. 1 is a schematic block diagram of the audio amplifier platform showing the preferred embodiment using class D amplifiers.

### DETAILED DESCRIPTION OF THE PREFERRED EMBODIMENTS

Detailed descriptions of the preferred embodiment are provided herein. It is to be understood, however, that the present invention may be embodied in various forms. Therefore, specific details disclosed herein are not to be interpreted as limiting, but rather as a basis for the claims and as a representative basis for teaching one skilled in the art to employ the present invention in virtually any appropriately detailed system, structure or manner.

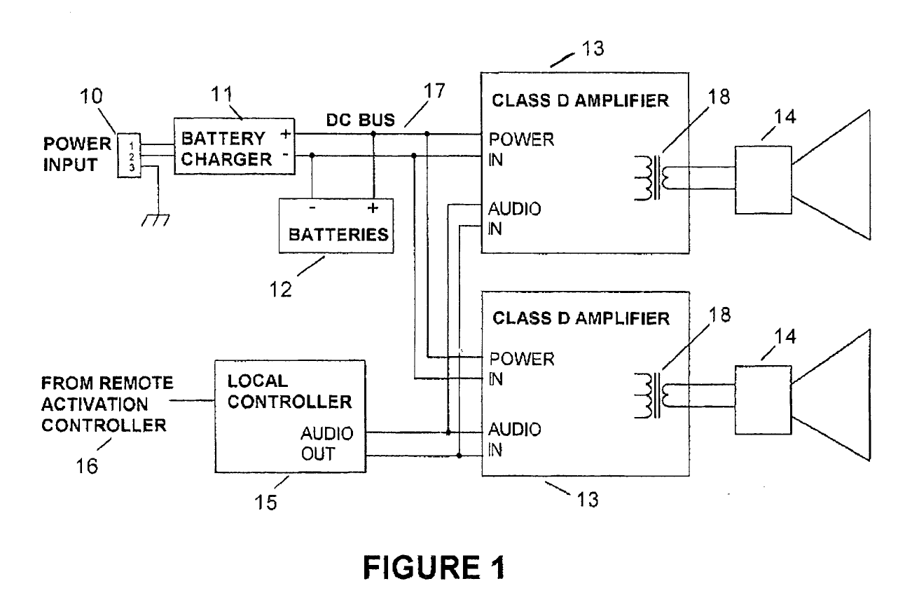

In accordance with the present invention, FIG. 1 shows the preferred embodiment of the invention. Referring to FIG. 1, a circuit for controlling and amplifying a low-level audio signal using a high efficiency class D switching amplifier is shown. A suitable source 10 of input power is applied to battery charger 11, which is configured to charge batteries 12. The batteries are suitably sized to supply power to operate the pair of class D amplifiers 13 at full output power for a predetermined time of usually at least 30 minutes. In the preferred embodiment, the circuit is powered by batteries 12 during activation with battery charger 11 supplying either a low standby charging current or a much higher current for recharging the batteries after activation. However, the input power source 10 could be applied to a conditioning and power supply section that is sized to operate the circuit directly, without the use of batteries, by connecting its output to DC bus 17 that supplies power to the class D amplifiers 13.

Not shown in FIG. 1 are protective devices such as fuses, circuit breakers and switches that provide protection against component failures, wiring shorts and allow for disconnection of power for maintenance and repairs. The DC voltage of bus 17 in the preferred embodiment is nominally 24 VDC, which is easy and economical to obtain from standard and readily available batteries. However, other bus voltages are easily accommodated by this design, since the Class D amplifiers use feedback to stabilize against load and input voltage variations and an output transformer to match the audio transducer impedance. The Class D amplifiers 13 in the preferred embodiment are designed to run off this single supply DC bus voltage directly.

The DC bus 17 power is applied to the class D amplifiers 13, which in the preferred application are each able to output full RMS power of over 2000 watts per amplifier for at least 30 minutes using a sine waveform as the tone inputs. The use of sin wave verses square wave drive tones for generating high power alerting signals improves the audio transducers efficiency and life expectancy. The class D amplifiers 13 used in the preferred embodiment are very compact and have an overall efficiency of greater than 90% independent of the amplitude and shape of the input audio signal.

In the preferred embodiment, the output of the class D amplifiers 13 connect to an array of acoustical transducers 14 sized to handle the total desired output power of their respective class D amplifiers 13. The impedance of the class D amplifier output is matched to the impedance of the acoustical transducer array using transformer 18, which can be either a non-isolated or an isolated transformer. The local controller 15 in the preferred embodiment contains tone generators for producing alert messages such as discrete or variable frequency tones as sirens. It may also contain stored messages, live public address interface, a link to a remote activation and control unit 16, as well as self and circuit diagnostics to determine system readiness to broadcast messages and monitor the proper operation of the system during an activation. The interface from the remote control unit 16 to the local controller 15 may take the form of fiber optics, ethernet, radio frequency (RF), phone lines or other forms of reliable long distance communications.

The circuit for controlling and amplifying a low-level audio signal using a high efficiency class D switching amplifiers as described above is usable as a cost effect means of public notification and emergency warning of both indoor and outdoor area.

The invention is susceptible of many embodiments. For example, there is within the scope of the invention and the claims, a circuit for controlling and amplifying a low level audio signal to an output acoustical transducer, consisting of a local controller providing a low level audio signal to a high efficiency Class D switching amplifier, which is connected to the audio transducer. There is a power conditioning section for converting AC or DC input power into DC power at the correct voltage for the amplifier. The power conditioning section may be a battery charger and batteries suitably sized to power the circuit for operation at full output power for a predetermined time.

The amplifier may have a sustained power output capability of at least about 100 watts RMS and an overall efficiency of greater than 80% independent of input waveform or input amplitude. The amplifier may be configured with an output transformer for impedance matching to the output acoustical transducer. The output transformer may be isolated or non-isolated. The local controller may be connected to a remote control unit.

As another example, there is a system for broadcasting audio messages, consisting of a local controller with at least one audio message source, where the controller is connected to a high efficiency Class D switching amplifier, and the amplifier is connected to an audio transducer. There is again a power conditioning section for converting AC or DC input power into DC power at the correct voltage for the amplifier, which may be a battery charger and batteries suitably sized to supply power to the system for operation at full output power for a predetermined time. The system may be configured in any of the ways described previously.

As yet another example, there is a system for broadcasting audio messages consisting of a local controller having at least one audio message source, where the controller is connected to multiple high efficiency Class D switching amplifiers, where each amplifier is connected to its own audio transducer or transducer array. There is again a power conditioning section for converting AC or DC input power into DC power at the correct voltage for the amplifiers.

The system may be configured in any of the ways described previously. The local controller may have a tone generator. It may have stored messages and a live public address interface. And it may have self and circuit diagnostic capability for determining system readiness to broadcast messages and monitor the proper operation of the system during an activation.

While the invention has been described in connection with a preferred embodiment, it is not intended to limit the scope of the invention to the particular form set forth, but on the contrary, it is intended to cover such alternatives, modifications, and equivalents as may be included within the spirit and scope of the invention as defined by the appended claims.

What is claimed is:

1. A circuit for controlling and amplifying a low level audio signal to an output acoustical transducer, comprising a local controller providing said low level audio signal to a high efficiency Class D switching amplifier connected to a said audio transducer, and a power conditioning section for converting AC or DC input power into DC power at the correct voltage for said amplifier.

2. A circuit for controlling and amplifying a low level audio signal according to claim 1, said amplifier having a sustained power output capability of at least about 100 watts RMS and an overall efficiency of greater than 80% independent of input waveform or input amplitude.

3. A circuit for controlling and amplifying a low level audio signal according to claim 2, said amplifier configured with an output transformer for impedance matching to said output acoustical transducer.

4. A circuit for controlling and amplifying a low level audio signal according to claim 3, said output transformer being an isolated transformer.

5. A circuit for controlling and amplifying a low level audio signal according to claim 3, said output transformer being a non-isolated transformer.

6. A circuit for controlling and amplifying a low level audio signal according to claim 1, said
power conditioning section comprising a battery charger and batteries suitably sized to power said circuit for operation at full output power for a predetermined time.

7. A system for broadcasting audio messages, comprising
a local controller having at least one audio message source, said controller connected to a high efficiency Class D switching amplifier, said amplifier connected to an audio transducer, and
a power conditioning section for converting AC or DC input power into DC power at the correct voltage for said amplifier.

8. A system for broadcasting audio messages according to claim 7, said amplifier having a sustained power output capability of at least about 100 watts RMS and an overall efficiency of greater than 80% independent of input waveform or input amplitude.

9. A system for broadcasting audio messages according to claim 8, said amplifier configured with an output transformer for impedance matching to said output acoustical transducer.

10. A system for broadcasting audio messages according to claim 9, said output transformer being an isolated transformer.

11. A system for broadcasting audio messages according to claim 9, said output transformer being a non-isolated transformer.

12. A system for broadcasting audio messages, comprising
a local controller having at least one audio message source, said controller connected to multiple high efficiency Class D switching amplifiers, each said amplifier being connected to an audio transducer array, and
a power conditioning section for converting AC or DC input power into DC power at the correct voltage for said amplifier.

13. A system for broadcasting audio messages according to claim 12, said amplifiers having a sustained power output capability of at least about 100 watts RMS and an overall efficiency of greater than 80% independent of input waveform or input amplitude.

14. A system for broadcasting audio messages according to claim 13, each said amplifier configured with an output transformer for impedance matching to said output acoustical transducer array.

15. A system for broadcasting audio messages according to claim 14, said output transformer being an isolated transformer.

16. A system for broadcasting audio messages according to claim 14, said output transformer being a non-isolated transformer.

17. A system for broadcasting audio messages according to claim 12, said local controller connected to a remote control unit.

18. A system for broadcasting audio messages according to claim 1, said power conditioning section comprising a battery charger and batteries suitably sized to supply power to said system for operation at full output power for a predetermined time.

19. A system for broadcasting audio messages according to claim 7, said local controller comprising a tone generator, stored messages, and a live public address interface.

20. A system for broadcasting audio messages according to claim 8, said local controller comprising self and circuit diagnostic capability for determining system readiness to broadcast messages and monitor the proper operation of the system during an activation.
